(19) United States
(12) Patent Application Publication
(10) Pub. No.: US 2004/0156228 A1
(43) Pub. Date: Aug. 12, 2004

(54) High density beta ratio independent core cell

(75) Inventor: Scott T. Becker, Darien, IL (US)

Correspondence Address: MARTINE & PENILLA, LLP, 710 LAKEWAY DRIVE, SUITE 170, SUNNYVALE, CA, 94085, US

(73) Assignee: Artisan Components, Inc., Sunnyvale, CA (US)

(21) Appl. No.: 10/364,283

(22) Filed: Feb. 10, 2003

(51) Int. Cl. G11C 11/00

(52) U.S. Cl. 365/154

(57) ABSTRACT

An invention for a memory core cell is provided. The memory core cell includes a storage cell, which is connected to differential writing circuitry. In addition, the storage cell is connected to single ended reading circuitry. In one aspect, the differential writing circuitry can include a pair of write bitlines coupled to the storage cell by a pair of write access transistors, with each write access transistor having a gate coupled to a write wordline. Also, the signal ended read circuitry can include a read transistor having a gate coupled to the storage element, a first terminal coupled to a read access transistor, and a second terminal coupled to ground. Further, the read access transistor can include a first terminal coupled to a read bitline, a second terminal coupled to the first terminal of the read access transistor, and a gate coupled to a read wordline.

### BACKGROUND OF THE INVENTION

1. Field of the Invention

This invention relates generally to random access memory architectures, and more particularly to a high density beta ratio independent core cell capable of avoiding read instability.

2. Description of the Related Art

Currently, random access memory (RAM) architectures include an array of memory cells, arranged as rows and columns, with each cell storing one bit of information. As is well known, the rows are accessed using wordlines and the columns are coupled via bitlines. Generally, storage capacity and operational speed of the memory are important attributes for systems requiring memory devices. Storage capacity refers to the amount of data that a memory device can store, and operational speed refers to the speed at which the memory device can store or retrieve data.

System access speed can often be dramatically increased through the use of mutliport memory architectures having two or more access ports. For example, a dual port memory has two access ports, allowing more than one system device to directly access the memory. In contrast, a single port memory permits direct coupling to only one system device, and as a result, other system. devices must contend for the port to gain access to the memory. By permitting direct coupling to more than one system device, overall system performance is usually enhanced.

FIG. 1 is a schematic diagram showing a conventional dual port memory cell 100 having one read and one write port. A write wordline 102 and a read wordline 104 address the dual port memory cell 100, which is defined by a write access transistor 106, a read access transistor 108, a first inverter 110, and a second inverter 112. The write access transistor 106 includes a first terminal coupled to a write bitline 116 and a second terminal coupled to both the input of the first inverter 110 and the output of the second inverter 112. In addition, the write access transistor 106 includes a gate coupled to the write wordline 102. The read access transistor 108 includes a gate coupled to the read wordline 104, a first terminal coupled to a read bitline 117, and a second terminal coupled a first terminal of read transistor 114, which includes a second terminal coupled to ground. The gate of read transistor 114 is coupled to both the output of the first inverter 110 and the input of the second inverter 112.

The value stored in dual port memory cell 100 depends on the voltage values stored on nodes 118a and 118b, which are the inverse of each other. Hence, when node 118a is high, node 118b is low, and vice versa. Generally, these node values are isolated from the write and read bitlines 116 and 117 until the core cell 100 is selected by driving the write or read wordlines 102 and 104 high.

During a read operation, the read wordline 104 is asserted high, which turns ON read access transistor 108 and electrically connects the read bitline 117 to the first terminal of the read transistor 114. Depending on the state node 118b, read transistor 114 either grounds the read bitline 117 or allows the precharge voltage to remain on the read bitline 117. Specifically, when node 118b is high, the read transistor turns ON and grounds the read bitline 117. Otherwise, the read transistor is OFF, allowing the read bitline 117 to remain high.

During a write operation, the write wordline is asserted high, which turns ON the write access transistor 106 and electrically connects the write bitline 116 to node 118a. In theory, the voltage on the write bitline 116 transfers to node 118a, thus writing the value of the write bitline 116 into the core cell 100. Unfortunately, to perform this operation, the write access transistor 106 must overcome inverter 112 before a new value can be written to the core cell 100. Since the write access transistor 106 is an n-channel transistor, the write access transistor 106 is not optimal for transferring high voltage values. Hence, writing a high value to node 118a when node 118a is low is difficult. Moreover, as voltage is lowered to reduce power, this situation is worsened. As a result, the pull down transistor within the second inverter 112 generally is designed to be weak by making the pull down transistor long. Unfortunately, long transistors consume a large area within an integrated circuit.

To address the problem of having long channel transistors, fully differential read and write dual port memory cells have been used. FIG. 2 is a schematic diagram showing a conventional dual port memory core cell 200 having fully differential read and write ports. As above, a write wordline 102 and a read wordline 104 address the dual port memory cell 200, which is defined by write access transistors 106a and 106b, read access transistors 108a and 108b, a first inverter 110, and a second inverter 112. The write access transistor 106a includes a first terminal coupled to a write bitline 116a and a second terminal coupled to both the input of the first inverter 110 and the output of the second inverter 112. The write access transistor 106b includes a first terminal coupled to a complementary write bitline 116b and a second terminal coupled to both the output of the first inverter 110 and the input of the second inverter 112. In addition, the gates of both write access transistors 106a and 106b are coupled to the write wordline 102.

The read access transistor 108a includes a first terminal coupled to a read bitline 117a and a second terminal coupled to both the input of the first inverter 110 and the output of the second inverter 112. The read access transistor 108b includes a first terminal coupled to a complementary read bitline 117b and a second terminal coupled to both the output of the first inverter 110 and the input of the second inverter 112. Further, the gates of both read access transistors 108a and 108b are coupled to the read wordline 104.

The differential write bitlines 116a and 116b allow the dual port memory core cell 200 to write data into the core cell without requiring the inverters 110 and 112 to have long pull down transistors. However, the dual port memory core cell 200 requires particular Beta ratios in order to perform read operations properly. The Beta ratio is the ratio of the resistance of the access transistors (i.e., transistors 106a/106b and 108a/108b) to the resistance of the pull down transistors within the core cell inverters (110 and 112) in a RAM storage element.

In the core cell 200, the Beta ratio affects a voltage level increase that occurs on the low node (118a or 118b) during a read operation. That is, the core cell stores high on one node and a low on the other node, and, during a read operation, both read bitlines 117a and 117b are initially precharged high. When the read access transistors 108a and 108b become active, an amount of voltage transfers from the bitline to core cell node (118a or 118b) that stores the low voltage value. The amount of voltage transferred is determined by the Beta ratio. For example, assuming node 118b is low, and assuming the resistance of the pull down transistor within inverter 110 is equal to the combined resistances of write access transistor 106b and read access transistor 108b, node 118b will initially charge to V_{DD}/2 during a read operation.

FIG. 3 is a graph 300 showing an initial voltage of the low core cell node in relation to the Beta ratio. As related to FIG. 2, the Beta ratio is the ratio of the resistances of the following transistors:

Beta Ratio=[R(transistor 106b)+R(transistor 108b)]/R(pull down in inverter 110) (1)

where R is the resistance of the particular transistor. Hence, when the resistance of the pull down transistor in inverter 110 is one third as large as the combined resistance of the two access transistors 106b and 108b (beta ratio equals 3), the voltage on node 118b initially rises to about V_{DD}/3 during a read operation. As the Beta ratio decreases, the more voltage is transferred to the low node, resulting in the low node increasing in voltage. Once the node voltage increases above the threshold of the pull down transistors in the inverters 110 and 112, the state of the core cell cannot be determined and core cell instability occurs.

To avoid core cell instability, a Beta ratio of about 2 is required. Hence, the resistance of the pull down transistors is required to be about one half that of the access transistors. As a result, size restrictions occur, which again increases area requirements.

In view of the foregoing, there is a need for a mutli-port, high density core cell. Further, the core cell should be Beta ratio independent to avoid increased area requirements, and should avoid core cell instability problems.

### SUMMARY OF THE INVENTION

Broadly speaking, the present invention fills these needs by providing a mutli-port, high density, Beta ratio independent core cell architecture. In one embodiment, a memory core cell is disclosed. The memory core cell includes a storage cell, which is connected to differential writing circuitry. In addition, the storage cell is connected to single ended reading circuitry. In one aspect, the differential writing circuitry can include a pair of write bitlines coupled to the storage cell by a pair of write access transistors, with each write access transistor having a gate coupled to a write wordline. Also, the signal ended read circuitry can include a read transistor having a gate coupled to the storage element, a first terminal coupled to a read access transistor, and a second terminal coupled to ground. Further, the read access transistor can include a first terminal coupled to a read bitline, a second terminal coupled to the first terminal of the read access transistor, and a gate coupled to a read wordline.

Optionally, the memory core cell can be extended by additional write and/or read ports. For example, a second set of differential writing circuitry can be connected to the storage cell. The second set of differential writing circuitry can include a second pair of write bitlines coupled to the storage cell by a second pair of write access transistors, with each write access transistor of the second pair of write access transistors having a gate coupled to a second write wordline. In addition, a second set of single ended reading circuitry can be connected to the storage cell. The second set of single ended read circuitry can include a second read access transistor having a first terminal coupled to a second read bitline, a second terminal coupled to the first terminal of the read access transistor, and a gate coupled to a second read wordline.

In an additional embodiment, a method is disclosed for making a memory cell. Storage transistors are arranged to generate a storage cell. Also, differential writing circuitry is connected to the storage cell, as is single ended reading circuitry. Since the memory core cell created is beta ratio independent, transistor size generally is not a design constraint. As a result, the transistors comprising the memory core cell can be formed such that the memory core cell has a minimum area. For example, the transistors comprising the memory core cell can be formed to be each minimum width transistors or minimum contacted width transistors, or both can be included in the memory core cell.

A generator for generating a multi port memory is disclosed in a further embodiment of the present invention. The generator includes logic that generates an arrangement of core cells and peripheral logic. In addition, the generator includes logic that connects differential writing circuitry to the storage cell based on predefined design rules, and logic that connects single ended reading circuitry to the storage cell based on predefined design rules. As mentioned above, the differential writing circuitry can include a pair of write bitlines coupled to the storage cell by a pair of write access transistors, with each write access transistor having a gate coupled to a write wordline. Also, the signal ended read circuitry can include a read transistor having a gate coupled to the storage element, a first terminal coupled to a read access transistor, and a second terminal coupled to ground. The read access transistor can include a first terminal coupled to a read bitline, a second terminal coupled to the first terminal of the read access transistor, and a gate coupled to a read wordline.

Advantageously, the embodiments of the present invention allow all the transistors to be minimum size, or otherwise sized to minimize the core cell area. Moreover, because the access transistors can be the same size as the inverter transistors of the storage element, the Beta ratio is small, which generates a larger initial voltage rise in the low node during a write operation. The larger initial voltage rise further weakens the p-channel transistors in the inverters, which decreases the time required for the core cell to change states.

Furthermore, read instability is not a concern using a multi port core cell of the embodiments of the present invention. Specifically, the only time the core cell is open to read instability is during a write operation, however during a write operation read instability is not a concern because the state of the core cell is not being read. Further, read operations are performed through transistor gates. As a result, read operations do not alter the voltages within the core cell. Other aspects and advantages of the invention will become apparent from the following detailed description, taken in conjunction with the accompanying drawings, illustrating by way of example the principles of the invention.

### BRIEF DESCRIPTION OF THE DRAWINGS

The invention, together with further advantages thereof, may best be understood by reference to the following description taken in conjunction with the accompanying drawings in which:

FIG. 1 is a schematic diagram showing a conventional dual port memory cell having one read and one write port;

FIG. 2 is a schematic diagram showing a conventional dual port memory core cell having fully differential read and write ports;

FIG. 3 is a graph showing an initial voltage of the low core cell node in relation to the Beta ratio;

FIG. 4 is a schematic diagram showing dual port Beta ratio independent core cell having one read port and one write port, in accordance with an embodiment of the present invention;

FIG. 5 is a graph showing node voltages on core cell during a differential write operation, in accordance with an embodiment of the present invention;

FIG. 6 is a schematic diagram showing a differential writing portion of a multi port memory core cell, in accordance with an embodiment of the present invention;

FIG. 7A is a diagram showing a portion of a minimum width transistor for use in a multi port core cell, in accordance with an embodiment of the present invention;

FIG. 7B is a diagram showing a portion of a minimum contacted width transistor for use in a multi port core cell, in accordance with an embodiment of the present invention;

FIG. 8 is a schematic diagram showing a three port memory core cell having two write ports and one read port, in accordance with an embodiment of the present invention;

FIG. 9 is a schematic diagram showing a three port memory core cell having two read ports and one write port, in accordance with an embodiment of the present invention;

FIG. 10A is a block diagram showing an exemplary simplified memory generator graphical user interface (GUI) front end, in accordance with an embodiment of the present invention; and

FIG. 10B is a block diagram showing an exemplary memory generator backend, in accordance with an embodiment of the present invention.

### DETAILED DESCRIPTION OF THE PREFERRED EMBODIMENTS

An invention is disclosed for a mutli-port, high density, Beta ratio independent core cell. In the following description, numerous specific details are set forth in order to provide a thorough understanding of the present invention. It will be apparent, however, to one skilled in the art that the present invention may be practiced without some or all of these specific details. In other instances, well known process steps have not been described in detail in order not to unnecessarily obscure the present invention.

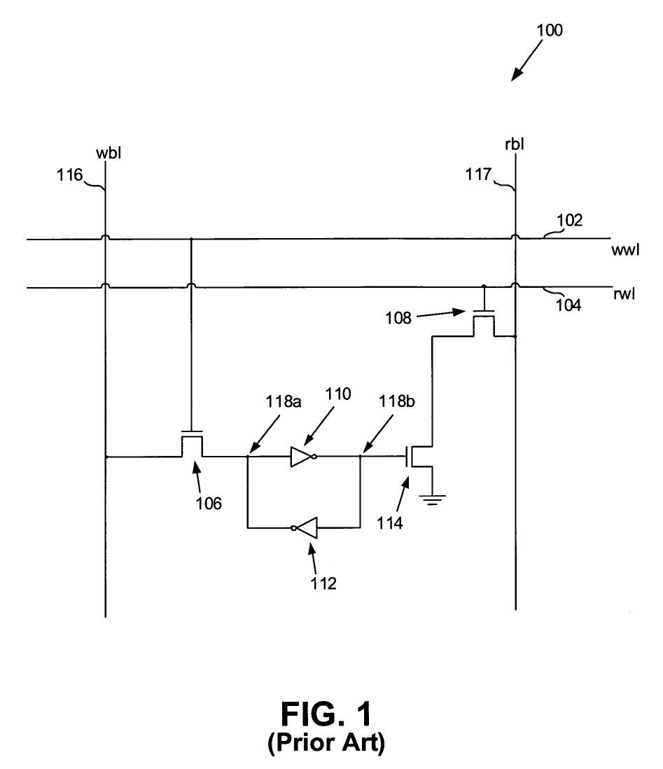

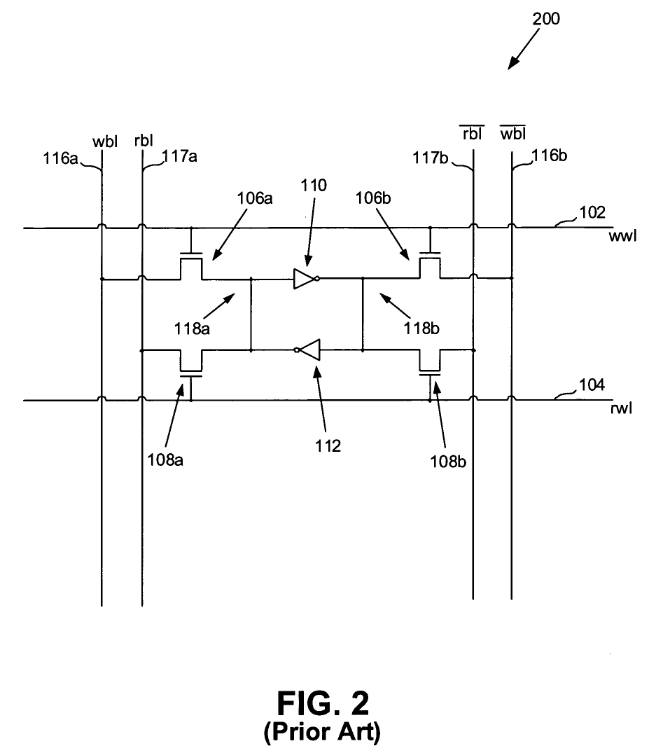

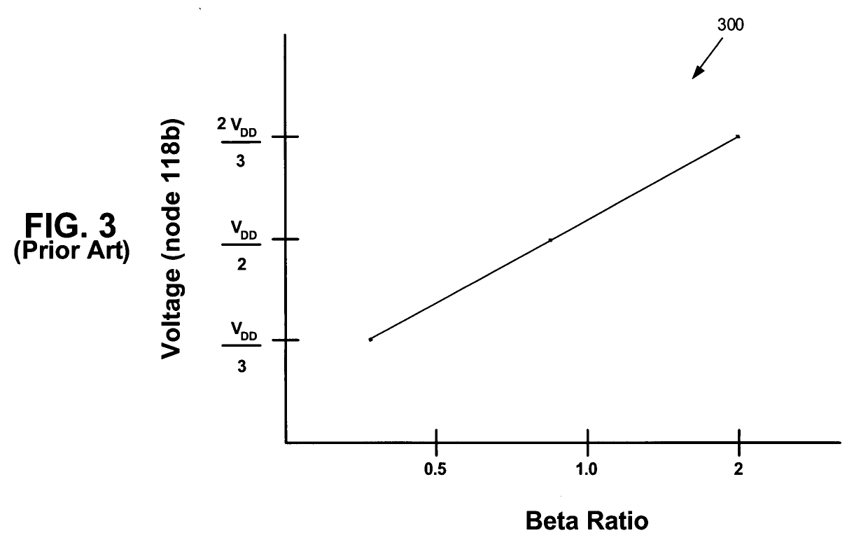

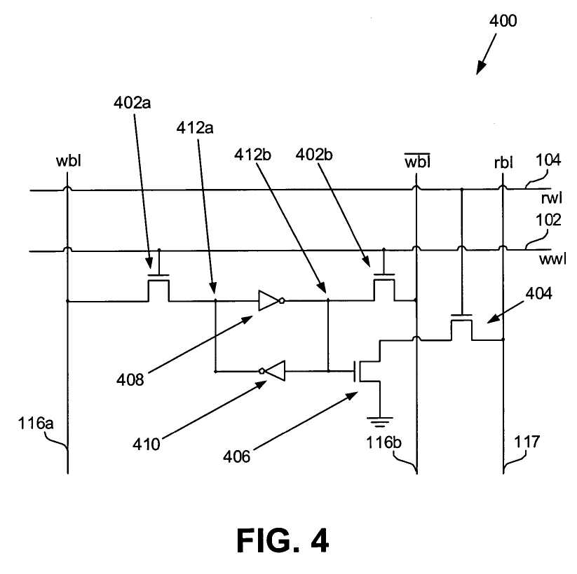

FIGS. 1-3 were described in terms of the prior art. FIG. 4 is a schematic diagram showing dual port Beta ratio independent core cell 400 having one read port and one write port, in accordance with an embodiment of the present invention. A write wordline 102 and a read wordline 104 address the dual port memory cell 400, which is defined by write access transistors 402a and 402b, a read access transistor 404, a read transistor 406, a first inverter 408, and a second inverter 410. The write access transistor 402a includes a first terminal coupled to a write bitline 116a and a second terminal coupled to both the input of the first inverter 408 and the output of the second inverter 410. The write access transistor 402b includes a first terminal coupled to a complementary write bitline 116b and a second terminal coupled to both the output of the first inverter 408 and the input of the second inverter 410. In addition, the gates of both write access transistors 402a and 402b are coupled to the write wordline 102.

The read access transistor 404 includes a gate coupled to the read wordline 104, a first terminal coupled a read bitline 117, and a second terminal coupled a first terminal of the read transistor 406, which includes a second terminal coupled to ground. The gate of the read transistor 406 is coupled to both the output of the first inverter 408 and the input of the second inverter 410.

As above, the value stored in dual port memory cell 400 depends on the voltage values stored on nodes 412a and 412b, which are the inverse of each other. Hence, when node 412a is high, node 412b is low, and vice versa. Generally, these node values are isolated from the write and read bitlines 116a/116b and 117 until the core cell 100 is selected by driving the write or read wordlines 102 and 104 high.

During a read operation, the read wordline 104 is asserted high, which turns ON read access transistor 404 and electrically connects the read bitline 117 to the first terminal of the read transistor 406. Depending on the state node 412b, read transistor 406 either grounds the read bitline 117 or allows the precharge voltage to remain on the read bitline 117. Specifically, when node 412b is high, the read transistor turns ON and grounds the read bitline 117. Otherwise, the read transistor is OFF, allowing the read bitline 117 to remain high.

During a write operation, the write bitlines 116a and 116b are set differentially and the write wordline 102 is asserted high. The high voltage on the write wordline 102 turns ON the write access transistors 402a and 402b, which electrically connects the differential bitlines 116a and 116b to the core cell nodes 412a and 412b respectively. Since the write bitlines 402a and 402b are in opposite states, there is a voltage “push” from one bitline and a voltage “pull” from the other bitline. As a result, changing the state of the core cell is more efficient because the write access transistors 402a and 402b are no longer required to overcome the pull down transistors within the inverters 408 and 410 without assistance.

Furthermore, since only read gates (i.e., the gate of read transistor 406) are coupled to the core cell, read operations do not affect the state of the core cell. Hence, embodiments of the present invention avoid read instability problems. That is, during write operations, read instability is not a problem because the core cell is being written to rather than being read. During read operations, read instability is not a problem because the read devices are only coupled to the core cell via transistor gates. As a result, the core cell 400 is Beta ratio independent.

For example, suppose node 412a stored a low value and node 412b stored a high value, and a write operation is performed in which an opposite value is to be stored in the core cell 400. Hence, write bitline 116a is charged to a high value and write bitline 116b is pulled low. When the write wordline 102 is asserted high, the high on write bitline 116a initially pulls up node 412a to about V_{DD}/3 based on the Beta ratio of the core cell. The V_{DD}/3 voltage on node 412a weakens the p-channel transistor within inverter 408. In addition, the low on the complementary write bitline 116b pulls down on the p-channel transistor within inverter 408 to lower the voltage on node 412b. The lower voltage on node 412b then weakens the n-channel pull down transistor within inverter 410. The weakened n-channel transistor within inverter 410 allows the voltage on node 412a to raise higher, which in turn further weakens the p-channel transistor within inverter 408. This positive feedback cycle then continues until the core cell flips, placing a high on node 412a and a low on node 412b.

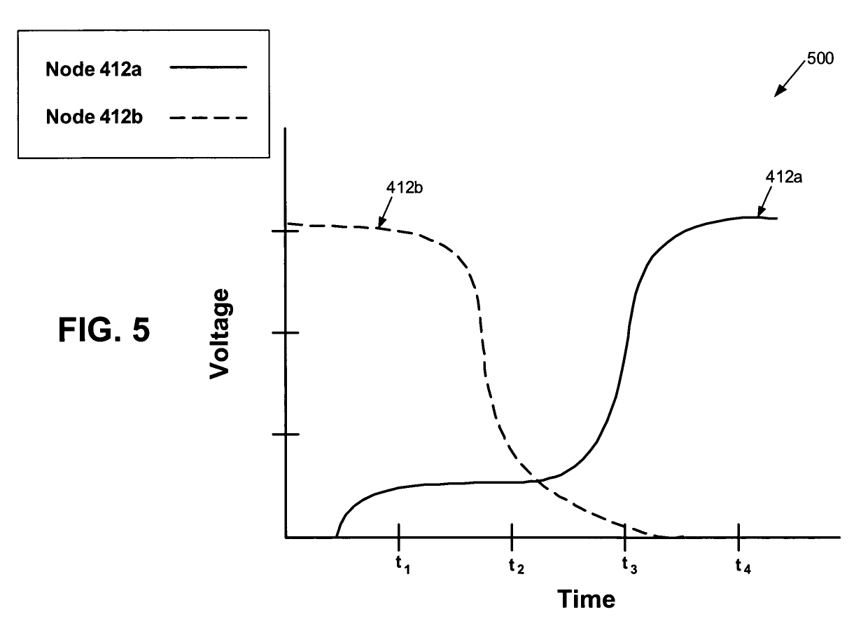

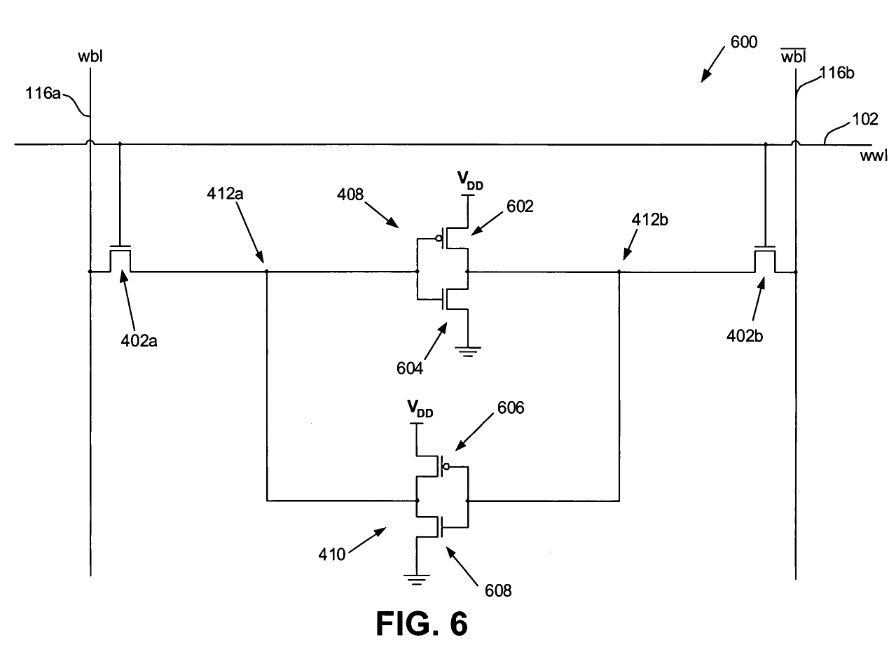

FIG. 5 is a graph 500 showing node voltages on core cell 400 during a differential write operation, in accordance with an embodiment of the present invention. As shown in FIG. 5, node 412b initially stores a high value and node 412a initially stores a low value. During the first t₁ nanoseconds, both write bitlines 116a and 116b are high, causing the voltage on node 412a to rise slightly. At time t₂ write bitline 116b is grounded in order to write to the core cell, and as a result, the voltage on node 412b begins to fall. Then, at time t₃, the positive feedback described above causes the core cell to flip, placing a high on node 412a and a low on node 412b. The above described “push” and “pull” differential writing operation can be seen in greater detail in FIG. 6, described next.

FIG. 6 is a schematic diagram showing a differential writing portion 600 of a multi port memory core cell, in accordance with an embodiment of the present invention. Specifically, FIG. 6 shows a detailed view of the differential writing portion 600 of a multi port memory core cell, including the transistors comprising the core cell inverters 408 and 410. As shown, inverter 408 includes a p-channel transistor 602 having a first terminal coupled to V_{DD}, a second terminal coupled to node 412b, and a gate coupled to node 412a. Inverter 408 further includes an n-channel transistor 604 having a first terminal coupled to node 412b, a second terminal coupled to ground, and a gate coupled to node 412a. Inverter 410 includes a p-channel transistor 606 having a first terminal coupled to V_{DD}, a second terminal coupled to node 412a, and a gate coupled to node 412b. Inverter 410 further includes an n-channel transistor 608 having a first terminal coupled to node 412a, a second terminal coupled to ground, and a gate coupled to node 412b. Although not shown in FIG. 6, it should be noted that the read transistors, bitline, and wordline as described with respect to FIG. 4 would generally be included in the multi port core cell.

Because the embodiments of the present invention utilize a differential write configuration and a single ended read configuration, the initial change in voltage on the core cell nodes based on the Beta ratio does not hinder the core cell operation. As a result, the write access transistors 402a and 402b can be the same size as the inverter transistors 602, 604, 606, 608, and 610. Advantageously, this allows all the transistors to be minimum size, or otherwise sized to minimize the core cell area. Moreover, because the access transistors 402a and 402b can be the same size as the inverter transistors 602, 604, 606, 608, and 610, the Beta ratio is small, which generates a larger initial voltage rise in the low node during a write operation. The larger initial voltage rise further weakens the p-channel transistors in the inverters, which decreases the time required for the core cell to change states.

Furthermore, read instability is not a concern using a multi port core cell of the embodiments of the present invention. Specifically, the only time the core cell 600 is open to read instability is during a write operation, however during a write operation read instability is not a concern because the state of the core cell is not being read. Further, read operations are performed through transistor gates. As a result, read operations do not alter the voltages within the core cell.

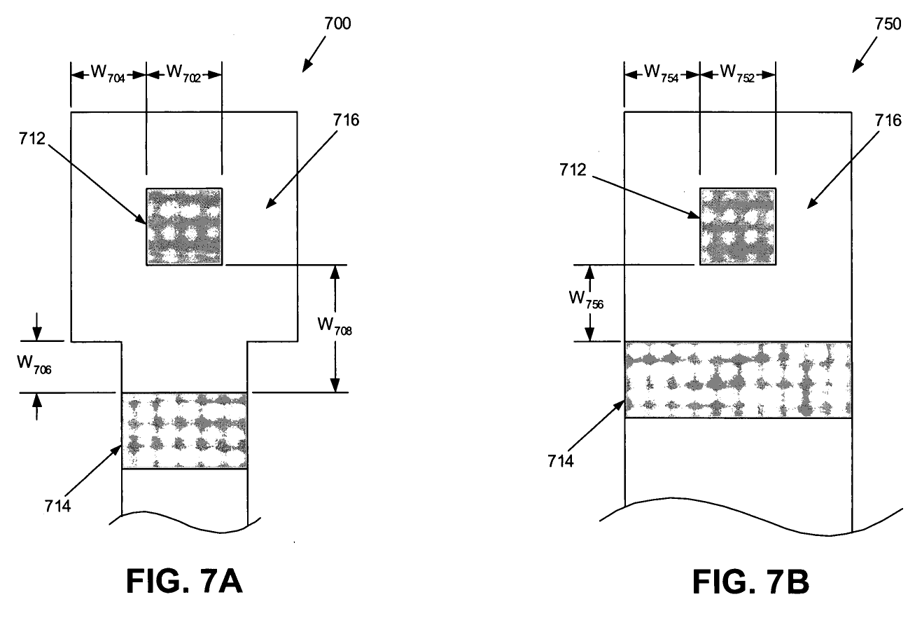

When fabricating transistors for use in the core cell, embodiments of the present invention can utilize any size transistor, including minimum width and minimum contacted width transistors. FIG. 7A is a diagram showing a portion of a minimum width transistor 700 for use in a multi port core cell, in accordance with an embodiment of the present invention. The minimum width transistor 700 includes a contact 712 surrounded by a diffusion layer 716, which is formed between the contact 712 and a gate polysilicon layer 714. When generating the minimum width transistor 700, the contact 712 is created with a particular width W₇₀₂. To ensure proper contact with the diffusion layer 716, the diffusion layer 716 is formed to have a particular width W₇₀₄ around the contact 712, which is known as diffusion overlap of contact.

The gate polysilicon layer 714 is formed a predefined minimum contact to gate distance W₇₀₈ away from the contact 712 to avoid shorting between the gate polysilicon layer 714 and the contact 712. Generally, the minimum width transistor 700 can have a gate width smaller than the sum of minimum contact width W₇₀₂ and the diffusion overlap of contact (i.e., W₇₀₂+2*W₇₀₄). However, generating the smaller gate width requires an additional minimum diffusion to poly spacing on field W₇₀₆. As a result, minimum diffusion to poly spacing on field W₇₀₆ typically increases the contact to gate distance W₇₀₈. To decrease the required contact to gate distance W₇₀₈, embodiments of the present invention can be implemented utilizing minimum contacted width transistors, as described next with reference to FIG. 7B.

FIG. 7B is a diagram showing a portion of a minimum contacted width transistor 750 for use in a multi port core cell, in accordance with an embodiment of the present invention. As with the minimum width transistor 700, the minimum contacted width transistor 750 includes a contact 712 surrounded by a diffusion layer 716, which is formed between the contact 712 and a gate polysilicon layer 714. When generating the minimum contacted width transistor 750, the contact 712 is created with a particular width W₇₅₂. To ensure proper contact with the diffusion layer 716, the diffusion layer 716 is formed to have a particular width W₇₅₄ around the contact 712.

The gate polysilicon layer 714 is formed a predefined minimum contact to gate distance W₇₅₆ away from the contact 712 to avoid shorting between the gate polysilicon layer 714 and the contact 712. As shown in FIG. 7B, the minimum contacted width transistor 750 has a gate width that is approximately the same width as the sum of minimum contact width W₇₅₂ and the diffusion overlap of contact (i.e., W₇₅₂+2*W₇₅₄). Because the gate width is not smaller than the sum of minimum contact width W₇₅₂ and the diffusion overlay of contact, the minimum diffusion to poly spacing on field is not required. As a result, the minimum contact to gate distance W₇₅₆ generally is smaller than the minimum contact to gate distance W₇₀₆ of the minimum contact transistor 700.

Hence, embodiments of the present invention can utilize minimum contacted width transistors for access transistors and inverter transistors to reduce the overall core cell size. However, in situations in which the overall core cell size can be better reduced using minimum width transistors, embodiments of the present invention can utilize minimum width transistors for access transistors and inverter transistors. Advantageously, all the core cell transistors can be minimum contacted width transistors or minimum width transistors because larger transistors are not required to overcome inverter transistors using the embodiments of the present invention.

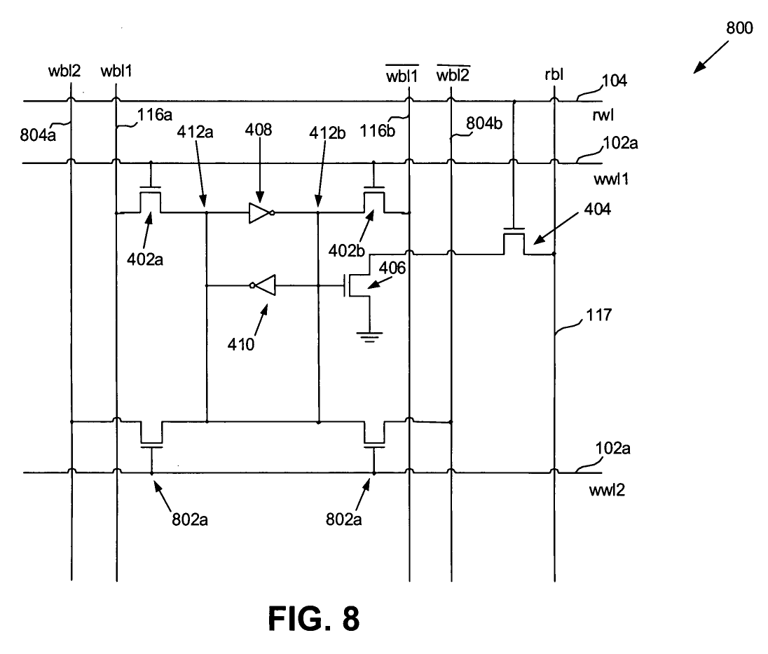

Although the multi port core cells of the embodiments of the present invention have thus far been described in terms of dual port memory core cells, it should be noted that the core cells of the embodiments of the present invention can be extended to include any number of ports. FIG. 8 is a schematic diagram showing a three port memory core cell 800 having two write ports and one read port, in accordance with an embodiment of the present invention.

A pair of write wordlines 102a and 102b, and a read wordline 104 address the multi port memory cell 800, which is defined by write access transistors 402a, 402b, 802a and 802b, a read access transistor 404, a read transistor 406, a first inverter 408, and a second inverter 410. The first write wordline 102a and write access transistors 402a and 402b control access to the core cell for the first write port. The write access transistor 402a includes a first terminal coupled to a first write bitline 116a and a second terminal coupled to both the input of the first inverter 408 and the output of the second inverter 410. The write access transistor 402b includes a first terminal coupled to a complementary first write bitline 116b and a second terminal coupled to both the output of the first inverter 408 and the input of the second inverter 410. In addition, the gates of both write access transistors 402a and 402b are coupled to the first write wordline 102a.

The second write wordline 102b and write access transistors 802a and 802b control access to the core cell for the second write port. The write access transistor 802a includes a first terminal coupled to a second write bitline 804a and a second terminal coupled to both the input of the first inverter 408 and the output of the second inverter 410. The write access transistor 802b includes a first terminal coupled to a complementary second write bitline 804b and a second terminal coupled to both the output of the first inverter 408 and the input of the second inverter 410. In addition, the gates of both write access transistors 802a and 802b are coupled to the second write wordline 102b.

The read access transistor 404 includes a gate coupled to the read wordline 104, a first terminal coupled a read bitline 117, and a second terminal coupled a first terminal of the read transistor 406, which includes a second terminal coupled to ground. The gate of the read transistor 406 is coupled to both the output of the first inverter 408 and the input of the second inverter 410.

The three port memory core cell 800 allows write operations to be performed using either the first write wordline 102a and the first write bitline pair 116a and 116b, or using the second write wordline 102b in conjunction with the second write bitline pair 804a and 804b. Further write ports can be added in a similar manner, using an additional write wordline and write bitline pair for each additional write port. Advantageously, additional write ports do not create read stability problems because the read operations are performed through transistor gates, as described previously. In addition to write ports, embodiments of the present invention can be further extended by adding additional read ports.

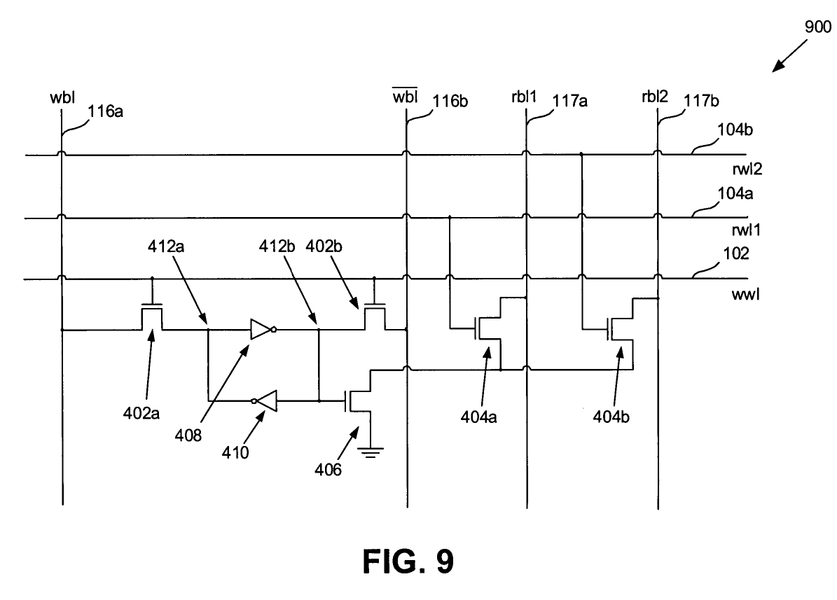

FIG. 9 is a schematic diagram showing a three port memory core cell 900 having two read ports and one write port, in accordance with an embodiment of the present invention. A write wordline 102 and a pair of read wordlines 104a and 104b address the multi port memory cell 900, which is defined by write access transistors 402a and 402b, read access transistors 404a and 404b, a read transistor 406, a first inverter 408, and a second inverter 410.

The write access transistor 402a includes a first terminal coupled to a write bitline 116a and a second terminal coupled to both the input of the first inverter 408 and the output of the second inverter 410. The write access transistor 402b includes a first terminal coupled to a complementary write bitline 116b and a second terminal coupled to both the output of the first inverter 408 and the input of the second inverter 410. In addition, the gates of both write access transistors 402a and 402b are coupled to the write wordline 102.

The first read wordline 104a and read access transistor 404a control access to the core cell for the first read port. The read access transistor 404a includes a gate coupled to the first read wordline 104a, a first terminal coupled the first read bitline 117a, and a second terminal coupled a first terminal of the read transistor 406, which includes a second terminal coupled to ground. The gate of the read transistor 406 is coupled to both the output of the first inverter 408 and the input of the second inverter 410. In a similar manner, the second read wordline 104b and read access transistor 404b control access to the core cell for the second read port. The read access transistor 404b includes a gate coupled to the second read wordline 104b, a first terminal coupled the second read bitline 117b, and a second terminal coupled a first terminal of the read transistor 406.

The three port memory core cell 900 allows read operations to be performed using either the first read wordline 104a and the first read bitline 117a, or using the second read wordline 104b in conjunction with the second read bitline 117b. Further read ports can be added in a similar manner, using an additional read wordline and read bitline for each additional read port. Because the read operations are performed through the transistor gate of the read transistor 406, read operations do not substantially alter voltages within the core cell. Hence, additional read ports advantageously do not create read stability problems.

In one embodiment, optimum placement and utilization of the techniques of the present invention is implemented utilizing a generator. The generator should be generally understood to include one or more generators, each generator can be specifically optimized for a particular task. Such tasks or sub-tasks, for example, can include generating a Beta ratio independent multi port memory core cell (e.g., as shown in FIG. 4) to be used with a memory device.

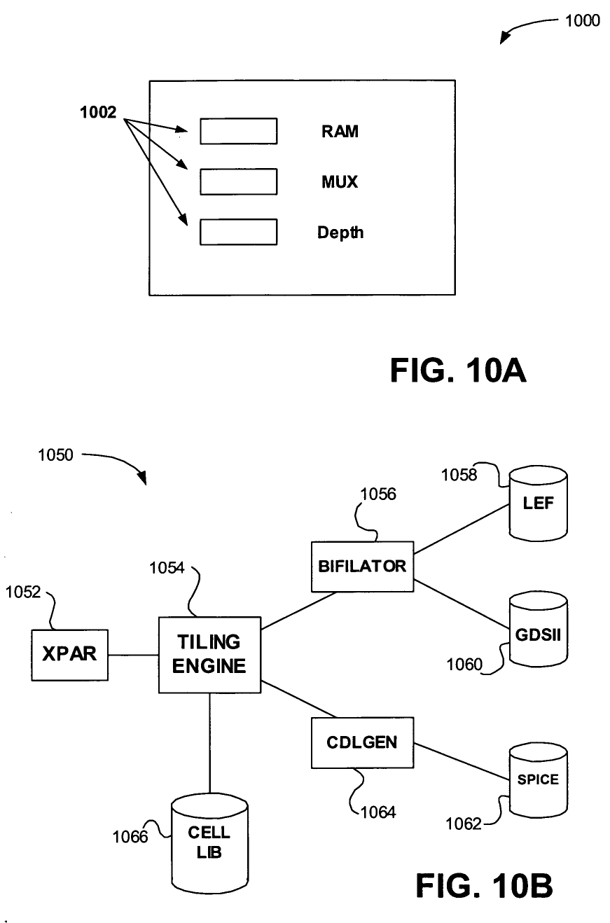

FIG. 10A is a block diagram showing an exemplary simplified memory generator graphical user interface (GUI) front end 1000, in accordance with an embodiment of the present invention. The exemplary memory generator GUI 1000 illustrates one view utilized for entering parameters into fields 1002 to define a particular memory application. Broadly speaking, the memory generator checks the validity of the entered data and executes appropriate generators to define the memory application. After receiving data utilizing the GUI front end view 1000, a memory generator of the embodiments of the present invention processes the data utilizing a memory generator backend, as described next with reference to FIG. 10B.

FIG. 10B is a block diagram showing an exemplary memory generator backend 1050, in accordance with an embodiment of the present invention. The memory generator backend 1050 comprises an XPAR process 1052, a tiling engine 1054, a Bifilator process 1056, a CDLGEN process 1064, and a cell library 1066. Generally speaking, these processes function together to generate a LEF model 1058, a GDSII model 1060, and a SPICE model 1062 for the particular memory application. The LEF model 1058 comprises place and route information, which is utilized by routers to manufacture integrated circuits. The GDSII model 1060 comprises mask layouts and is utilized by semiconductor foundries. The SPICE model 1062 includes circuit interconnection definitions, operational properties, and schematic diagrams of the memory application. Thus, the designer can use the SPICE model of the application for cross verification.

As mentioned above, the exemplary memory generator backend 1050 processes the data received via the GUI front end 1000. More specifically, the XPAR process 1052 encapsulates the rules needed to utilize particular cell layouts stored in the cell library. These rules, along with the parameter data for the memory application are then provided to the tiling engine 1054 for optimization and cell placement. By separating the functions of the XPAR process 1052 from those of the tiling engine 1054, individual rules can be altered for specific applications without altering the functions and placement algorithms utilized in the timing engine 1054.

The Bifilator process 1056 generates an interface around a particular device or memory array. Generally, on a RAM there may exist over one thousand routing points for interfacing with the RAM. As a result, the entire routing configuration may change when a user changes the placement of the RAM, requiring intense reconfiguration. To address this issue, the Bifilator process 1056 builds an interface around the RAM, which the user can use to interface with the RAM without configuring each routing point.

The present invention may be implemented using any type of integrated circuit logic, state machines, or software driven computer-implemented operations. By way of example, a hardware description language (HDL) based design and synthesis program may be used to design the silicon-level circuitry necessary to appropriately perform the data and control operations in accordance with one embodiment of the present invention.

The invention may employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing.

Any of the operations described herein that form part of the invention are useful machine operations. The invention also relates to a device or an apparatus for performing these operations. The apparatus may be specially constructed for the required purposes, or it may be a general purpose computer selectively activated or configured by a computer program stored in the computer. In particular, various general purpose machines may be used with computer programs written in accordance with the teachings herein, or it may be more convenient to construct a more specialized apparatus to perform the required operations.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A memory core cell, comprising:
a storage cell;
differential writing circuitry connected to the storage cell; and
single ended reading circuitry connected to the storage cell.

2. A memory core cell as recited in claim 1, wherein the differential writing circuitry includes a pair of write bitlines coupled to the storage cell by a pair of write access transistors, each write access transistor having a gate coupled to a write wordline.

3. A memory core cell as recited in claim 2, wherein the single ended read circuitry includes a read transistor having a gate coupled to the storage element, a first terminal coupled to a read access transistor, and a second terminal coupled to ground.

4. A memory core cell as recited in claim 3, wherein the read access transistor includes a first terminal coupled to a read bitline, a second terminal coupled to the first terminal of the read access transistor, and a gate coupled to a read wordline.

5. A memory core cell as recited in claim 4, wherein the storage element includes a pair of inverters, each inverter including a p channel and an n channel transistor.

6. A memory core cell as recited in claim 5, wherein the transistors forming the memory core cell are selected to generate a memory core cell having a minimum area.

7. A memory core cell as recited in claim 5, wherein the transistors forming the memory core cell are each minimum width transistors.

8. A memory core cell as recited in claim 5, wherein the transistors forming the memory core cell are each minimum contacted width transistors.

9. A memory core cell as recited in claim 1, further comprising a second set of differential writing circuitry connected to the storage cell, the second set of differential writing circuitry including a second pair of write bitlines coupled to the storage cell by a second pair of write access transistors, each write access transistor of the second pair of write access transistors having a gate coupled to a second write wordline.

10. A memory core cell as recited in claim 1, further comprising a second set of single ended reading circuitry connected to the storage cell, the second set of signal ended read circuitry including a second read access transistor having a first terminal coupled to a second read bitline, a second terminal coupled to the first terminal of the read access transistor, and a gate coupled to a second read wordline.

11. A memory core cell as recited in claim 1, wherein the memory is designed using a generator.

12. A method for making a memory cell, comprising the operations of:
arranging storage transistors of a storage cell;
connecting differential writing circuitry to the storage cell; and
connecting single ended reading circuitry to the storage cell.

13. A method as recited in claim 12, wherein the differential writing circuitry includes a pair of write bitlines coupled to the storage cell by a pair of write access transistors, each write access transistor having a gate coupled to a write wordline.

14. A method as recited in claim 13, wherein the single ended read circuitry includes a read transistor having a gate coupled to the storage element, a first terminal coupled to a read access transistor, and a second terminal coupled to ground.

15. A method as recited in claim 14, wherein the read access transistor includes a first terminal coupled to a read bitline, a second terminal coupled to the first terminal of the read access transistor, and a gate coupled to a read wordline.

16. A method as recited in claim 15, further comprising the operation of forming the transistors comprising the memory core cell such that the memory core cell has a minimum area.

17. A method as recited in claim 15, further comprising the operation of forming the transistors comprising the memory core cell to be each minimum width transistors.

18. A method as recited in claim 15, further comprising the operation of forming the transistors comprising the memory core cell to be each minimum contacted width transistors.

19. A generator for generating a multi port memory, comprising:
logic that assembles a plurality of memory cells into a functional memory based on predefined design rules,
wherein at least one memory cell comprises:
a storage cell;
differential writing circuitry connected to the storage cell; and
single ended reading circuitry connected to the storage cell.

20. A generator as recited in claim 19, wherein the differential writing circuitry includes a pair of write bitlines coupled to the storage cell by a pair of write access transistors, each write access transistor having a gate coupled to a write wordline.

21. A generator as recited in claim 20, wherein the single ended read circuitry includes a read transistor having a gate coupled to the storage element, a first terminal coupled to a read access transistor, and a second terminal coupled to ground, and wherein the read access transistor includes a first terminal coupled to a read bitline, a second terminal coupled to the first terminal of the read access transistor, and a gate coupled to a read wordline.

22. A generator as recited in claim 21, wherein the transistors forming the memory core cell are selected to generate a memory core cell having a minimum area.

23. A generator as recited in claim 21, wherein the transistors forming the memory core cell are each minimum width transistors.

24. A generator as recited in claim 21, wherein the transistors forming the memory core cell are each minimum contacted width transistors.
